(19) United States
(12) Patent Application Publication
(10) Pub. No.: US 2025/0344382 A1
(43) Pub. Date: Nov. 6, 2025

(54) SEMICONDUCTOR DEVICE AND METHOD WITH MEMORY CELLS HAVING COUPLING GATE SELF-ALIGNED TO FLOATING GATE

(71) Applicant: Silicon Storage Technology, Inc., San Jose, CA (US)

(72) Inventors: Jeng-Wei Yang, Zhubei City (TW); MAN-TANG WU., Hsinchu (TW); HIEU VAN TRAN, San Jose, CA (US); XIAN LIU, Sunnyvale, CA (US); NHAN DO, Saratoga, CA (US)

(21) Appl. No.: 18/805,395

(22) Filed: Aug. 14, 2024

Related U.S. Application Data
(60) Provisional application No. 63/641,651, filed on May 2, 2024.

(51) Int. Cl. H10B 41/30; H01L 29/423; H01L 29/788; H10B 41/40

(52) U.S. Cl. CPC H10B 41/30; H10B 41/40; H10D 30/68; H10D 30/6892

(57) ABSTRACT

A semiconductor device that comprises source and drain regions formed in a semiconductor substrate with a channel region extending there between, a floating gate disposed over a first portion of the channel region, a select gate disposed over a second portion of the channel region, and a coupling gate having a first portion disposed over the source region and laterally adjacent to a side surface of the floating gate, and a second portion disposed over an upper surface of the floating gate. The coupling gate is insulated from the source region and from the floating gate by an insulation layer having a uniform thickness between the first portion of the coupling gate and the source region, the first portion of the coupling gate and the side surface of the floating gate, and the second portion of the coupling gate and the upper surface of the floating gate.

### RELATED APPLICATIONS

This application claims the benefit of U.S. Provisional Application No. 63/641,651, filed May 2, 2024, and which is incorporated herein by reference.

### FIELD OF THE INVENTION

The present disclosure relates to non-volatile memory semiconductor devices, and in particular a method of forming non-volatile memory cells with self-aligned gates as well as a method of operating such memory cells.

### BACKGROUND OF THE INVENTION

Semiconductor devices with split-gate non-volatile memory cells utilizing floating gates to store charges thereon, and memory arrays of such non-volatile memory cells, are well known in the art. See for example U.S. Pat. Nos. 7,315,056 and 8,711,636, which are incorporated herein by reference for all purposes.

There is a need to scale down the size of the memory cells while maintaining performance, so that more memory cells can fit in the same square area of the semiconductor device. There is also a need to simplify the processing steps needed to form the semiconductor device. Finally, there is a need to reduce the necessary operational voltages and power consumption during the operation of the semiconductor device.

### BRIEF SUMMARY OF THE INVENTION

The aforementioned problems and needs are addressed by a semiconductor device that comprises a semiconductor substrate, a source region and a drain region formed in the semiconductor substrate, with a channel region of the semiconductor substrate extending between the source region and the drain region, a floating gate disposed over and insulated from a first portion of the channel region, a select gate disposed over and insulated from a second portion of the channel region, and a coupling gate having a first portion disposed over and insulated from the source region and laterally adjacent to a side surface of the floating gate, and a second portion disposed over and insulated from an upper surface of the floating gate, wherein the coupling gate is insulated from the source region and from the floating gate by an insulation layer having a uniform thickness between the first portion of the coupling gate and the source region, the first portion of the coupling gate and the side surface of the floating gate, and the second portion of the coupling gate and the upper surface of the floating gate.

A method of forming a semiconductor device comprises forming a source region and a drain region in a semiconductor substrate, with a channel region of the semiconductor substrate extending between the source region and the drain region, forming a floating gate disposed over and insulated from a first portion of the channel region, forming an insulation layer having a uniform thickness on the semiconductor substrate over the source region and over a second portion of the channel region, on a side surface of the floating gate, and on an upper surface of the floating gate, forming a select gate disposed over a second portion of the channel region, wherein the select gate is insulated from the second portion of the channel region by the insulation layer, and forming a coupling gate having a first portion disposed over the source region and laterally adjacent to the side surface of the floating gate, and a second portion disposed over the upper surface of the floating gate, wherein the coupling gate is insulated from the source region and from the floating gate by the insulation layer having the uniform thickness between the first portion of the coupling gate and the source region, the first portion of the coupling gate and the side surface of the floating gate, and the second portion of the coupling gate and the upper surface of the floating gate.

Other objects and features of the present disclosure will become apparent by a review of the specification, claims and appended figures.

### BRIEF DESCRIPTION OF THE DRAWINGS

FIGS. 1-12 are side cross sectional views showing the formation of a semiconductor device.

FIG. 13 is a side cross sectional view of the first area of the semiconductor device.

FIG. 14 is a side cross sectional view of the second and third areas of the semiconductor device.

FIGS. 15-16 are side cross sectional views showing an alternate example of the formation of an semiconductor device.

### DETAILED DESCRIPTION OF THE INVENTION

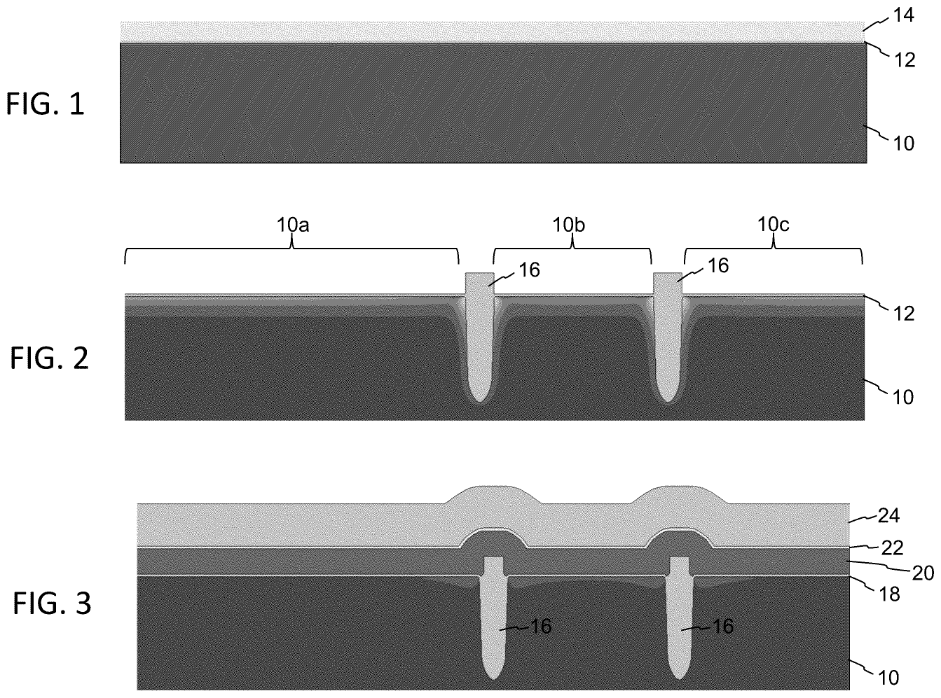

The present disclosure is directed to a method of forming a semiconductor device with split-gate non-volatile memory cells, and a method of operating such memory cells. FIGS. 1-12 illustrate the method of forming the semiconductor device 1. The method begins by forming an insulation layer 12 such as oxide (i.e., silicon oxide, silicon dioxide, or a combination thereof) on an upper surface of a semiconductor substrate 10 (e.g., a silicon substrate). An insulation layer 14 such as silicon nitride (“nitride”) is formed on the oxide insulation layer 12, as shown in FIG. 1. The structure is then patterned by photolithography (e.g., a photoresist is formed on the structure, which is selectively developed and removed to expose portions of the underlying layer, whereby the exposed portions of the underlying layer is removed by for example an etch). In the present case trenches are formed through the nitride insulation layer 14, oxide insulation layer 12 and into the semiconductor substrate 10. The trenches are then filled with insulation material 16 (which is known as STI—shallow trench isolation). The nitride insulation layer 14 is then removed by for example an etch, with the resulting structure shown in FIG. 2. The semiconductor substrate 10 can include a first area 10a, a second area 10b and a third area 10c, which can be insulated from each other by insulation material 16.

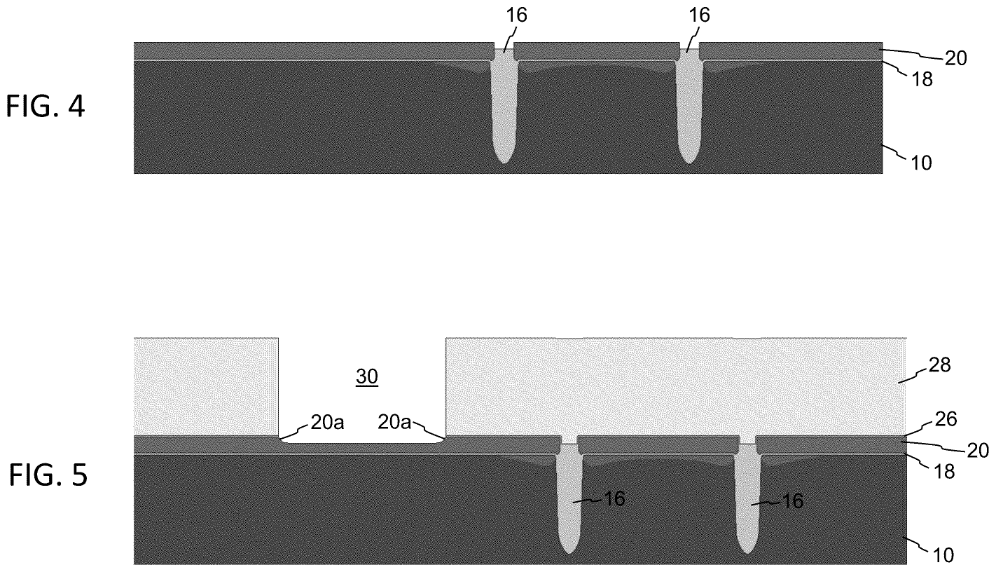

Oxide insulation layer 12 is removed by for example an etch. An oxide insulation layer 18 is formed on the structure, and a first conductive layer 20 (e.g., polysilicon) is formed on oxide insulation layer 18. A nitride insulation layer 22 is formed on first conductive layer 20. An oxide insulation layer 24 is formed on nitride insulation layer 22, as shown in FIG. 3. Oxide insulation layer 24 is removed by a chemical mechanical polish, leaving gaps in the nitride insulation layer 22 over insulation material 16. An etch is used to remove portions of the first conductive layer 20 over insulation material 16, exposing insulation material 16. One or more etches can be used to recess the tops of insulation material 16 (relative to the upper surface of first conductive layer 20), and remove nitride insulation layer 22, as shown in FIG. 4.

An oxide insulation layer 26 is formed on the first conductive layer 20. A nitride insulation layer 28 is formed on oxide insulation layer 26. The nitride insulation layer 28 is patterned (photoresist is formed, selectively developed and removed to expose portions of nitride insulation layer 28, followed by an etch to form a trench 30 into a portion of nitride insulation layer 28 in the first area 10a, with the trench 30 extending down to and exposing oxide insulation layer 26. One or more etches can be used to remove oxide insulation layer 26 at the bottom of the trench 30, and to recess the upper surface of first conductive layer 20 at the bottom of the trench 30 so that the upper surface of the first conductive layer 20 has non-planar portions 20a adjacent the side walls of the trench 30. The resulting structure is shown in FIG. 5 (after the removal of the photoresist).

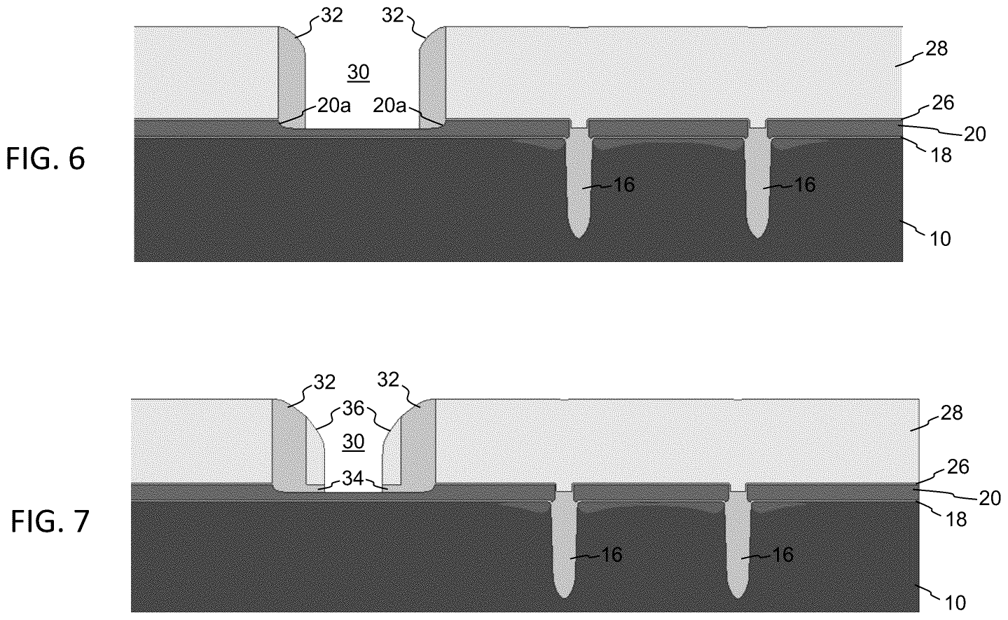

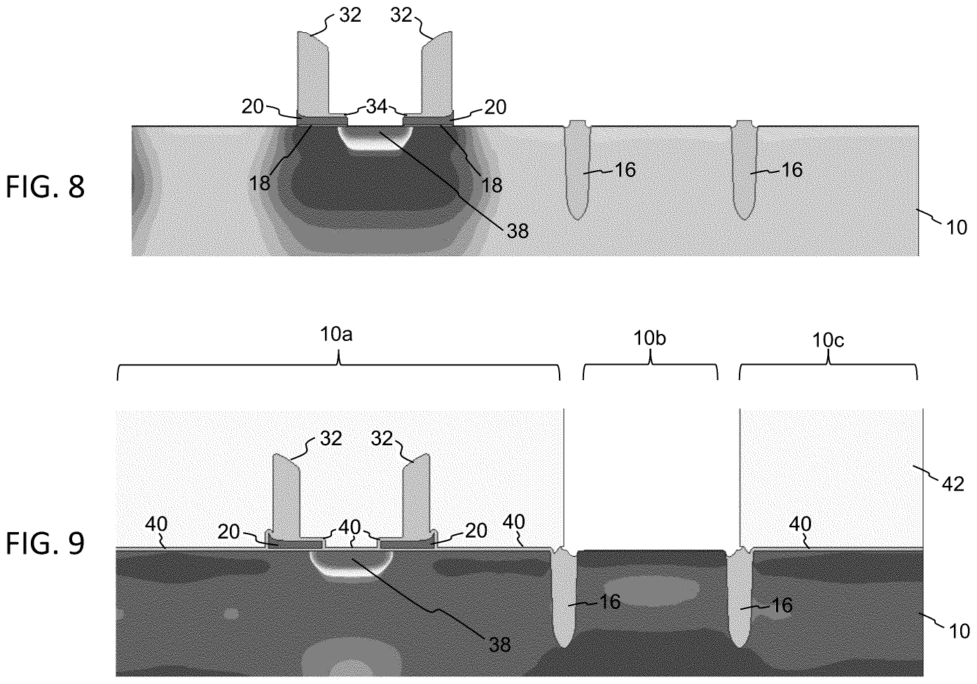

Oxide insulation spacers 32 are formed in the trench 30 by oxide deposition and etch, which removes the deposited oxide except for oxide insulation spacers 32 along the vertical sidewalls of the trench 30 (and over non-planar portions 20a of conductive layer 20), as shown in FIG. 6. An oxide insulation layer 34 is formed over the structure, followed by the formation of a nitride insulation layer on oxide insulation layer 34. An etch is then used to remove the nitride insulation layer except for nitride insulation spacers 36 in the trench 30, abutting the oxide insulation spacers 32 and over oxide insulation layer 34 (which is removed from the area between the nitride insulation spacers 36 to expose the underlying portion of the first conductive layer 20, as shown in FIG. 7. An implantation and anneal are performed to form source region 38 in the semiconductor substrate 10 underneath trench 30 and between nitride insulation spacers 36. One or more etches are performed to remove nitride insulation layer 28, nitride insulation spacers 36, oxide insulation layer 26, first conductive layer 20 and oxide insulation layer 18, except for portions of first conductive layer 20 and oxide insulation layer 18 disposed under oxide insulation spacers 32 and oxide insulation layer 34, as shown in FIG. 8.

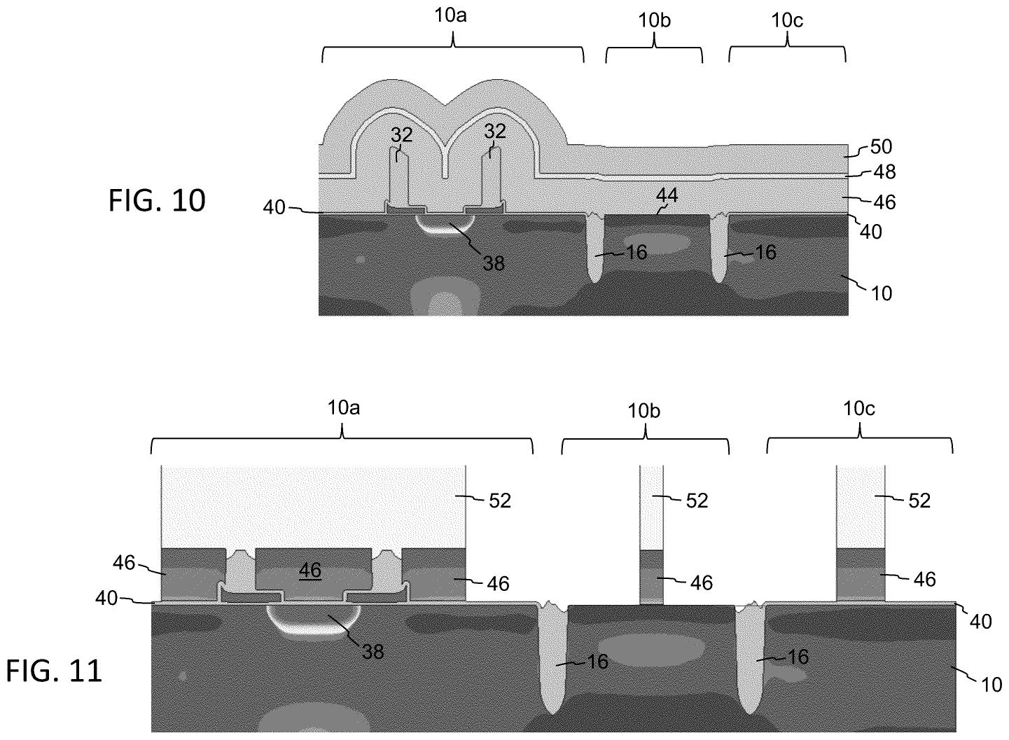

An etch can be used to remove remaining portions of oxide insulation layer 34, which also thins oxide insulation spacers 32 to expose the sharp edges 20b of first conductive layer 20 where non-planar portions 20a meet side surfaces of the remaining portions of first conductive layer 20. An oxide insulation layer 40 is formed over the structure, including over the exposed surfaces of first conductive layer 20 and the substrate 10. A masking step is performed to remove the oxide insulation layer 40 from the second area 10b. Specifically, photoresist 42 is formed over the structure, and removed from the second area 10b. An etch is then used to remove oxide insulation layer 40 from the second area 10b. The resulting structure is shown in FIG. 9. An oxide insulation layer 44 is formed on the upper surface of the semiconductor substrate 10 in the second area 10b. After the photoresist 42 is removed, a second conductive layer 46 (e.g., polysilicon) is formed over the structure. A nitride insulation layer 48 is formed on second conductive layer 46. An oxide insulation layer 50 is formed on the nitride insulation layer 48. The resulting structure is shown in FIG. 10.

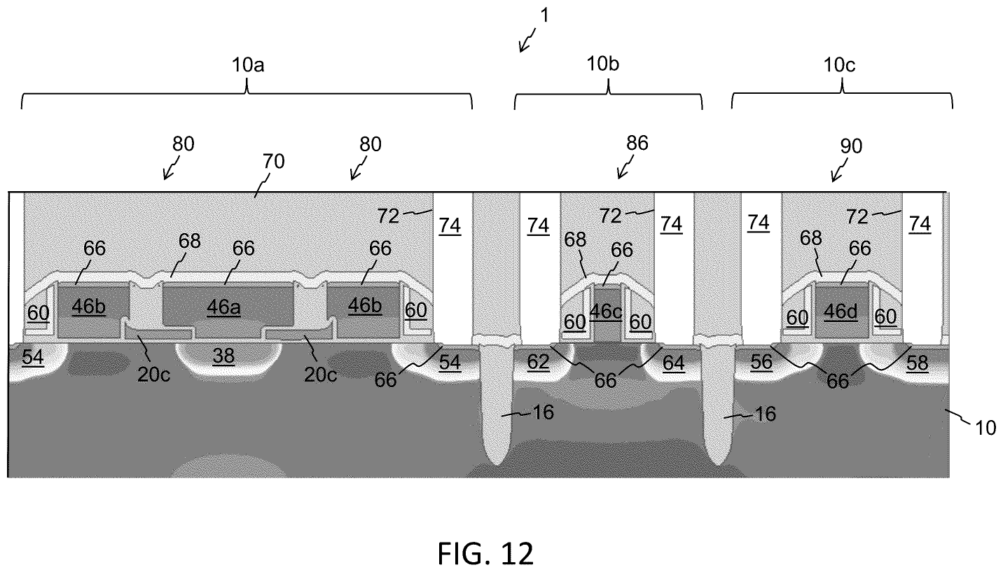

A chemical mechanical process is performed to planarize the structure, which can stop on nitride insulation layer 48. One or more etches can be used to etch down the exposed upper surface of the second conductive layer 46 and remove remaining portions of nitride insulation layer 48. The structure is then patterned to selectively remove portions of second conductive layer 46. Specifically, photoresist 52 is formed over the structure and selectively removed to expose selective portions of second conductive layer 46 in the first, second and third areas 10a, 10b, 10c, which can then be removed by an etch, as shown in FIG. 11. Photoresist is formed over the structure and removed from the first area 10a and third area 10c. An implantation is then performed to form drain regions 54 in the first area 10a, and second source region 56 and second drain region 58 in the third area 10c. After photoresist removal, composite insulation spacers 60 (e.g., of oxide and nitride) are formed along the exposed sides of second conductive layer 46 by material deposition and etch. Photoresist is formed over the structure and removed from the second area 10b. An implantation is then performed to third source region 62 and third drain region 64 in the second area 10b. After photoresist removal, metal material is deposited and annealed to form silicide 66 on the exposed surfaces of second conductive layer 46, drain regions 54, second source region 56, second drain region 58, third source region 62 and third drain region 64. The unreacted metal material is then removed. A nitride insulation layer 68 is formed over the structure, and oxide insulation material 70 is formed on nitride insulation layer 68. Oxide insulation material 70 can be patterned to form contact holes 72 that extend down to and expose drain regions 54, second source region 56, second drain region 58, third source region 62 and third drain region 64. The contact holes 72 are filled with conductive material to form electrical contacts 74. The final semiconductor device 1 is shown in FIG. 12.

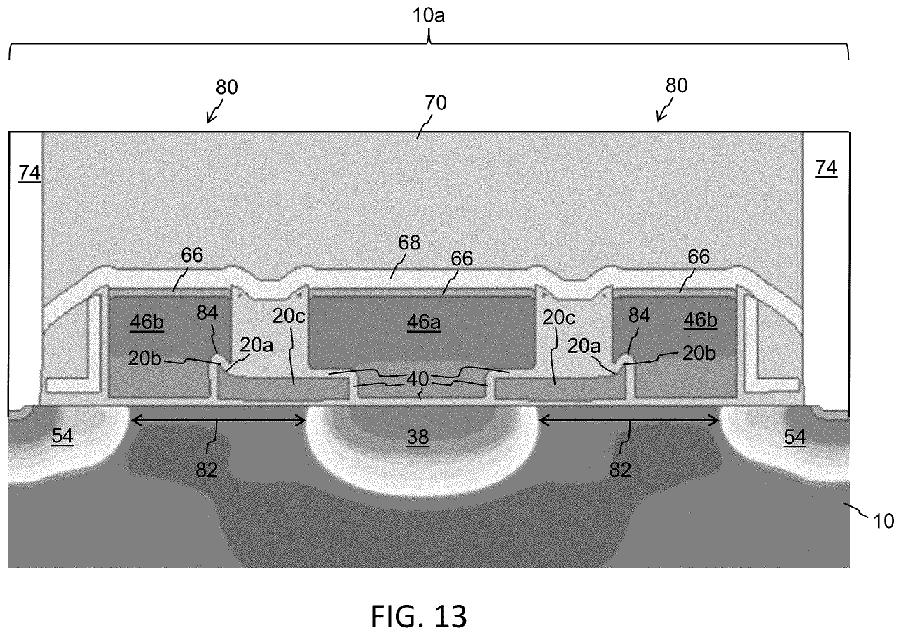

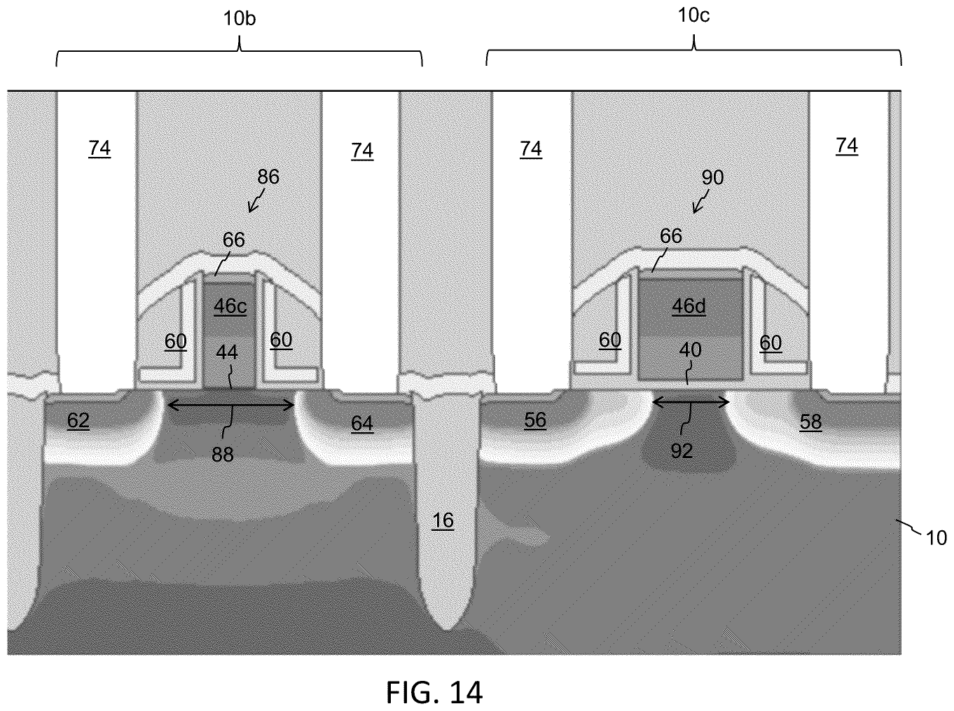

As best shown in FIGS. 12 and 13, a pair of memory cells 80 are formed in the first area 10a. It should be noted that while only a pair of memory cells 80 are shown, many pairs of such memory cells can be formed in the first area 10a. Each memory cell 80 includes a channel region 82 of the semiconductor substrate 10 extending between the source region 38 and the drain region 54. A floating gate 20c is disposed over and insulated from (and controls the conductivity of) a first portion of the channel region 82. A select gate 46b is disposed over and insulated from (and controls the conductivity of) a second portion of the channel region 82. The select gate 46b includes a cavity 84 that faces the sharp edge 20b of the floating gate 20c. A coupling gate 46a is shared between the pair of memory cells 80. For each memory cell 80, the coupling gate 46a includes a first portion disposed over and insulated from the source region 38 and laterally adjacent to a side surface of the floating gate 20c, and a second portion that is disposed over an upper surface of the floating gate 20c. The coupling gate 46a is insulated from the source region 38, the side surface of floating gate 20c, and the upper surface of floating gate 20c, by oxide insulation layer 40 that has a uniform thickness.

Exemplary voltages for reading, erasing and programming the memory cell 80 are provided in the following tables.

TABLE 1

| | Select | | Drain | | Coupling | | Source | |
|---|---|---|---|---|---|---|---|---|
| Operation | Gate 46b | | Region 54 | | Gate 46a | | Region 38 | |
| Read | 2.5 | V | 0.8 | V | 0 | V | 0 | V |
| Erase | 13 | V | 0 | V | 0 | V | 0 | V |

| | | | | | | | |
|---|---|---|---|---|---|---|---|
| Program | 1 V-1.5 V | 2.5-5.0 | μA | 7.5 | V | 6.5 | V |

TABLE 2

| | Select | Drain | | Coupling | | Source | |
|---|---|---|---|---|---|---|---|
| Operation | Gate 46b | Region 54 | | Gate 46a | | Region 38 | |
| Read | 2.5 V | 0.8 | V | 0 | V | 0 | V |
| Erase | 8.5 V | 0 | V | −8.5 | V | 0 | V |
| Program | 1 V-1.5 V | 2.5-5.0 | μA | 7.5 | V | 6.5 | V |

TABLE 3

| | Select | | Drain | | Coupling | | Source | |
|---|---|---|---|---|---|---|---|---|
| Operation | Gate 46b | | Region 54 | | Gate 46a | | Region 38 | |
| Read | 2.5 | V | 0.8 | V | 0-3 | V | 0 | V |
| Erase | 13 | V | 0 | V | 0 | V | 0 | V |

| | | | | | | | |
|---|---|---|---|---|---|---|---|
| Program | 1 V-1.5 V | 2.5-5.0 | μA | 7.5 | V | 6.5 | V |

TABLE 4

| | Select | Drain | | Coupling | | Source | |
|---|---|---|---|---|---|---|---|
| Operation | Gate 46b | Region 54 | | Gate 46a | | Region 38 | |
| Read | 2.5 V | 0.8 | V | 0-3 | V | 0 | V |
| Erase | 8.5 V | 0 | V | −8.5 | V | 0 | V |
| Program | 1 V-1.5 V | 2.5-5.0 | μA | 7.5 | V | 6.5 | V |

During the program operation, heated electrons traveling through the channel region 82 become heated and are injected onto the floating gate 20c by hot electron injection. During the erase operation, electrons tunnel from sharp edge 20b of floating gate 20c, through oxide insulation layer 40, and onto select gate 46b. During the read operation, the portion of the channel region 82 under select gate 46b is turned on (i.e., is conductive), whereby the conductivity of the portion of the channel region 82 under the floating gate 20c (which is controlled by the electron charge on the floating gate 20c) is measured by detecting the current through the channel region 82.

As best shown in FIGS. 12 and 14, a first logic device 86 is formed in the second area 10b. It should be noted that while only one first logic device 86 is shown, many such first logic devices can be formed in the second area 10b. First logic device 86 includes a third channel region 88 of the semiconductor substrate 10 extending between the third source region 62 and the third drain region 64. A first logic gate 46c is disposed over and insulated from (and controls the conductivity of) the third channel region 88. The oxide insulation layer 44 between the first logic gate 46c and the third channel region 88 is relatively thin for low voltage operation.

As best shown in FIGS. 12 and 14, a second logic device 90 is formed in the third area 10c. It should be noted that while only one second logic device 90 is shown, many such second logic devices can be formed in the third area 10c. Second logic device 90 includes a second channel region 92 of the semiconductor substrate 10 extending between the second source region 56 and the second drain region 58. A second logic gate 46d is disposed over and insulated from (and controls the conductivity of) the second channel region 92. The oxide insulation layer 40 between the second logic gate 46d and the second channel region 92 is relatively thick for high voltage operation (i.e., the oxide insulation layer 40 is thicker than the oxide insulation layer 44 so that second logic device 90 can operate at a higher voltage than the first logic device 86).

The semiconductor device 1, and the method of its formation, have many advantages. Two polysilicon layers, formed using two distinct and different polysilicon layer deposition processes, are used to form all the gates of the memory cells 80, the first logic devices 86 and the second logic devices 90. The sharp edge 20b of floating gate 20c facing cavity 84 of select gate 46b enhances erase efficiency of the memory cells. The coupling gate 46a is self-aligned to the floating gate 20c in a precise and controllable way, by virtue of the uniform thickness of oxide insulation layer 40 (i.e., the insulation material separation is uniform between the side and upper surfaces of the floating gate 20c and the coupling gate 46a, so that the coupling gate 46a wraps around the side and upper surfaces of the floating gate 20c separated therefrom by a uniform thickness insulation layer), which enhances capacitive coupling between the coupling gate 46a and floating gate 20c for better read, erase and program performance and allowing for reduced operational voltages during these operations. The method allows for fewer masking/patterning steps, and for scaling down the dimensions of the memory cells and reducing manufacturing costs. Silicide 66 increases the conductivity of the various gates and source and drain regions. First logic device 86 and second logic device 90 are formed on the same substrate 10, but configured for different operational voltages. First logic device 86 is configured to operate at a relatively low operational voltage by virtue of a thinner oxide insulation layer 44 between first logic gate 46c and substrate 10, and channel region 88 extending at least partially under composite insulation spacers 60 (because third source region 62 and third drain region 64 are formed after the formation of composite insulation spacers 60). Second logic device 90 is configured to operate at a higher operational voltage than first logic device 86 by virtue of a thicker oxide insulation layer 40 between second logic gate 46d and substrate 10 (i.e., oxide insulation layer 44 is thinner than oxide insulation layer 40), and channel region 92 does not extend under composite insulation spacers 60 (because second source region 56 and second drain region 58 are formed before the formation of composite insulation spacers 60).

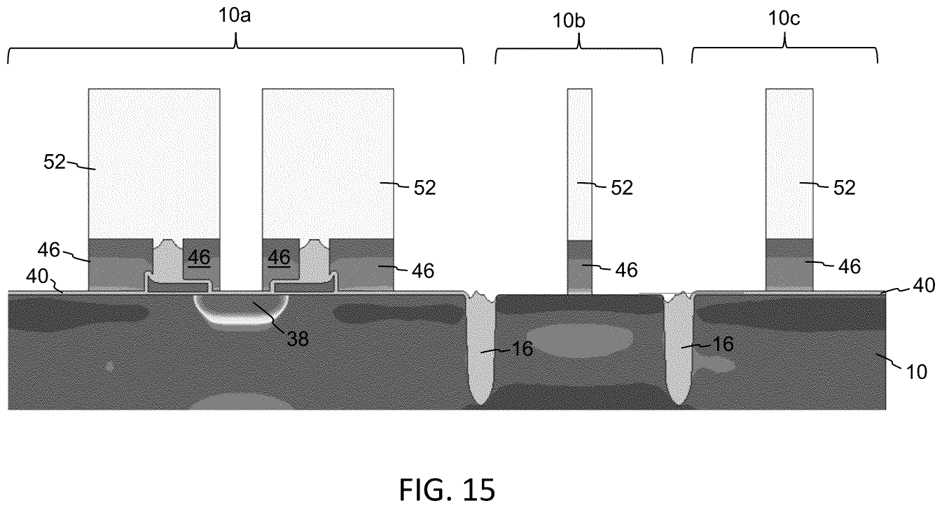

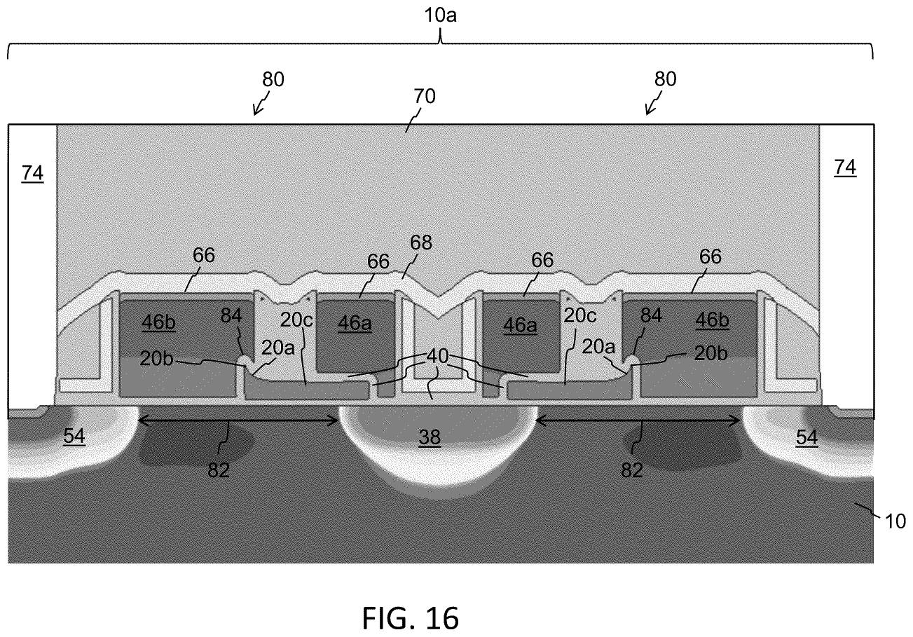

FIGS. 15-16 illustrate an alternate example. This example starts with the same structure as that in FIG. 10. However, the patterning described above with respect to FIG. 11 is modified so that the portion of the second conductive layer 46 over the source region 38 is separated into two distinct blocks, as shown in FIG. 15. The same processing described above with respect to FIG. 12 is then performed to result in the pair of memory cells 80 of FIG. 16, which is the same as the pair of memory cells in FIG. 13 except there are two coupling gates 46a over source region 38 (one for each of the two memory cells 80), instead of just one coupling gate 46a shared between the pair of memory cells 80. This example provides a pair of memory cells 80 each with its own coupling gate 46a that can be operated independently from the other coupling gate 46a for the pair of memory cells 80 sharing a common source region 38.

It is to be understood that the present disclosure is not limited to the example(s) described above and illustrated herein, but encompasses any and all variations falling within the scope of any claims. For example, any references to the present disclosure or invention or examples herein are not intended to limit the scope of any claim or claim term, but instead merely make reference to one or more features that may be covered by one or more claims. Materials, processes and numerical examples described above are exemplary only, and should not be deemed to limit the claims. For example, various insulation layers and spacers are disclosed as being formed of oxide or nitride. However, these materials are examples only, and any appropriate insulation material could be used for any given insulation layer or spacer. Similarly, other conductive materials can be used for the polysilicon. Further, not all method operations need be performed in the exact order illustrated or claimed, but rather in any order (unless there is an explicitly recited limitation on any order) that allows the proper formation of the semiconductor devices described herein. Single layers of material could be formed as multiple layers of such or similar materials, and vice versa. Lastly, the terms “forming” and “formed” as used herein shall include material deposition, material growth, or any other technique in providing the material as disclosed or claimed.

What is claimed is:

1. A semiconductor device, comprising:
a semiconductor substrate;
a source region and a drain region formed in the semiconductor substrate, with a channel region of the semiconductor substrate extending between the source region and the drain region;
a floating gate disposed over and insulated from a first portion of the channel region;
a select gate disposed over and insulated from a second portion of the channel region; and
a coupling gate having a first portion disposed over and insulated from the source region and laterally adjacent to a side surface of the floating gate, and a second portion disposed over and insulated from an upper surface of the floating gate, wherein the coupling gate is insulated from the source region and from the floating gate by an insulation layer having a uniform thickness between the first portion of the coupling gate and the source region, the first portion of the coupling gate and the side surface of the floating gate, and the second portion of the coupling gate and the upper surface of the floating gate.

2. The semiconductor device of claim 1, wherein the floating gate includes a sharp edge and the select gate includes a cavity facing the sharp edge.

3. The semiconductor device of claim 1, further comprising:
a second drain region in the semiconductor substrate, with a second channel region of the semiconductor substrate extending between the source region and the second drain region;
a second floating gate disposed over and insulated from a first portion of the second channel region; and
a second select gate disposed over and insulated from a second portion of the second channel region;
wherein the first portion of the coupling gate is laterally adjacent to a side surface of the second floating gate, and the coupling gate includes a third portion disposed over and insulated from an upper surface of the second floating gate, and wherein the coupling gate is insulated from the second floating gate by the insulation layer having the uniform thickness between the first portion of the coupling gate and the side surface of the second floating gate, and the third portion of the coupling gate and the upper surface of the second floating gate.

4. The semiconductor device of claim 3, wherein the second floating gate includes a second sharp edge and the second select gate includes a cavity facing the second sharp edge.

5. The semiconductor device of claim 1, further comprising:
a second drain region in the semiconductor substrate, with a second channel region of the semiconductor substrate extending between the source region and the second drain region;
a second floating gate disposed over and insulated from a first portion of the second channel region;
a second select gate disposed over and insulated from a second portion of the second channel region; and
a second coupling gate having a first portion disposed over and insulated from the source region and laterally adjacent to a side surface of the second floating gate, and a second portion disposed over and insulated from an upper surface of the second floating gate, wherein the second coupling gate is insulated from the source region and from the second floating gate by the insulation layer having a uniform thickness between the first portion of the second coupling gate and the source region, the first portion of the second coupling gate and the side surface of the second floating gate, and the second portion of the second coupling gate and the upper surface of the second floating gate.

6. The semiconductor device of claim 5, wherein the second floating gate includes a second sharp edge and the second select gate includes a cavity facing the second sharp edge.

7. The semiconductor device of claim 1, further comprising:
a first logic device comprising:
a second source region and a second drain region formed in the semiconductor substrate, with a second channel region of the semiconductor substrate extending between the second source region and the second drain region, and
a first logic gate disposed over and insulated from the second channel region by a second insulation layer, wherein the second insulation layer is thinner than the insulation layer; and
a second logic device comprising:
a third source region and a third drain region formed in the semiconductor substrate, with a third channel region of the semiconductor substrate extending between the third source region and the third drain region, and
a second logic gate disposed over and insulated from the third channel region by the insulation layer.

8. The semiconductor device of claim 7, further comprising:
first insulation spacers formed along side surfaces of the first logic gate, wherein the second channel region extends at least partially under the first insulation spacers; and
second insulation spacers formed along side surfaces of the second logic gate, wherein no portion of the third channel region extends under the second insulation spacers.

9. A method of forming a semiconductor device, comprising:
forming a source region and a drain region in a semiconductor substrate, with a channel region of the semiconductor substrate extending between the source region and the drain region;
forming a floating gate disposed over and insulated from a first portion of the channel region;
forming an insulation layer having a uniform thickness on the semiconductor substrate over the source region and over a second portion of the channel region, on a side surface of the floating gate, and on an upper surface of the floating gate;
forming a select gate disposed over a second portion of the channel region, wherein the select gate is insulated from the second portion of the channel region by the insulation layer; and
forming a coupling gate having a first portion disposed over the source region and laterally adjacent to the side surface of the floating gate, and a second portion disposed over the upper surface of the floating gate, wherein the coupling gate is insulated from the source region and from the floating gate by the insulation layer having the uniform thickness between the first portion of the coupling gate and the source region, the first portion of the coupling gate and the side surface of the floating gate, and the second portion of the coupling gate and the upper surface of the floating gate.

10. The method of claim 9, wherein:
the forming of the floating gate includes forming a sharp edge between the side surface of the floating gate and the upper surface of the floating gate; and
the forming of the select gate includes forming a cavity in the select gate that faces the sharp edge.

11. The method of claim 9, further comprising:
forming a second drain region in the semiconductor substrate, with a second channel region of the semiconductor substrate extending between the source region and the second drain region;
forming a second floating gate disposed over and insulated from a first portion of the second channel region, wherein the forming of the insulation layer includes forming the insulation layer having the uniform thickness on the semiconductor substrate over a second portion of the second channel region, on a side surface of the second floating gate, and on an upper surface of the second floating gate; and
forming a second select gate disposed over the second portion of the second channel region, wherein the second select gate is insulated from the second portion of the second channel region by the insulation layer;
wherein the first portion of the coupling gate is laterally adjacent to the side surface of the second floating gate, and the coupling gate includes a third portion disposed over and insulated from the upper surface of the second floating gate, and wherein the coupling gate is insulated from the second floating gate by the insulation layer having the uniform thickness between the first portion of the coupling gate and the side surface of the second floating gate, and the third portion of the coupling gate and the upper surface of the second floating gate.

12. The method of claim 11, wherein:
the forming of the second floating gate includes forming a second sharp edge between the side surface of the second floating gate and the upper surface of the second floating gate; and
the forming of the second select gate includes forming a cavity in the second select gate that faces the second sharp edge.

13. The method of claim 9, further comprising:
forming a second drain region in the semiconductor substrate, with a second channel region of the semiconductor substrate extending between the source region and the second drain region;
forming a second floating gate disposed over and insulated from a first portion of the second channel region, wherein the forming of the insulation layer includes forming the insulation layer having the uniform thickness on the semiconductor substrate over a second portion of the second channel region, on a side surface of the second floating gate, and on an upper surface of the second floating gate;
forming a second select gate disposed over the second portion of the second channel region, wherein the second select gate is insulated from the second portion of the second channel region by the insulation layer; and
forming a second coupling gate having a first portion disposed over and insulated from the source region and laterally adjacent to a side surface of the second floating gate, and a second portion disposed over and insulated from an upper surface of the second floating gate, wherein the second coupling gate is insulated from the source region and from the second floating gate by the insulation layer having the uniform thickness between the first portion of the second coupling gate and the source region, the first portion of the second coupling gate and the side surface of the second floating gate, and the second portion of the second coupling gate and the upper surface of the second floating gate.

14. The method of claim 13, wherein:
the forming of the second floating gate includes forming a second sharp edge between the side surface of the second floating gate and the upper surface of the second floating gate; and
the forming of the second select gate includes forming a cavity in the second select gate that faces the second sharp edge.

15. The method of claim 9, further comprising:
forming a first logic device by:
forming a second source region and a second drain region in the semiconductor substrate, with a second channel region of the semiconductor substrate extending between the second source region and the second drain region, and
forming a first logic gate disposed over and insulated from the second channel region by a second insulation layer, wherein the second insulation layer is thinner than the insulation layer; and
forming a second logic device by:
forming a third source region and a third drain region in the semiconductor substrate, with a third channel region of the semiconductor substrate extending between the third source region and the third drain region, wherein the forming of the insulation layer includes forming the insulation layer having the uniform thickness on the semiconductor substrate over a third channel region, and
forming a second logic gate disposed over and insulated from the third channel region by the insulation layer.

16. The method of claim 15, further comprising:
forming first insulation spacers along side surfaces of the first logic gate, wherein the second channel region extends at least partially under the first insulation spacers; and
forming second insulation spacers along side surfaces of the second logic gate, wherein no portion of the third channel region extends under the second insulation spacers.

17. The method of claim 16, wherein:
the first insulation spacers are formed before the forming of the second source region and the second drain region; and
the second insulation spacers are formed after the forming of the third source region and the third drain region.
